(19) United States
(12) Patent Application Publication
(10) Pub. No.: US 2017/0063306 A1
(43) Pub. Date: Mar. 2, 2017

(54) GATE INDUCED DRAIN LEAKAGE REDUCTION

(71) Applicant: QUALCOMM Incorporated, San Diego, CA (US)

(72) Inventor: Khaled Abdelfattah, Laguna Hills, CA (US)

(21) Appl. No.: 14/939,894

(22) Filed: Nov. 12, 2015

Related U.S. Application Data
(60) Provisional application No. 62/210,817, filed on Aug. 27, 2015.

(51) Int. Cl. H03F 1/02; H03F 3/21; H03F 3/193

(52) U.S. Cl. CPC H03F 1/0205; H03F 3/193; H03F 3/211; H03F 2200/294; H03F 2200/451; H03F 2203/21106

(57) ABSTRACT

Exemplary embodiments of the present disclosure are related to reducing, and possibly preventing, gate inducted drain leakage for a switch. A device may comprise an amplifier and at least one transistor coupled in a feedback path of the amplifier. The device may also comprise a circuit configured to modulate a gate of the at least one transistor with a signal comprising a scaled-down and shifted version of a signal at a drain of the at least one transistor.

### CROSS-REFERENCE TO RELATED APPLICATIONS

This application claims the benefit of priority from U.S. Provisional Patent Application No. 62/210,817 entitled “REDUCING GATE INDUCED DRAIN LEAKAGE IN A SWITCH,” filed on Aug. 27, 2015, the entire contents of which are incorporated herein by reference.

### BACKGROUND

Field

The present disclosure relates generally to electronic switches. More specifically, the present disclosure includes embodiments related to leakage in electronic switches.

Background

Electronic devices (e.g., cellular telephones, wireless modems, computers, digital music players, global positioning system (GPS) units, personal digital assistants (PDAs), gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of electronic circuits to support the processor and other parts of the device.

Switches are commonly used in various electronic circuits such as a transceiver in a wireless communication device. Switches may be implemented with various types of transistors such as metal oxide semiconductor (MOS) transistors. A switch may receive an input signal at one terminal and a control signal. The switch may pass the input signal to another terminal if it is turned on by the control signal and may block the input signal if it is turned off by the control signal. It may be desirable to obtain good performance and high reliability for the switch.

### BRIEF DESCRIPTION OF THE DRAWINGS

FIG. 1 shows a wireless device communicating with a wireless system, according to an exemplary embodiment of the present disclosure.

FIG. 2 shows a block diagram of the wireless device in FIG. 1.

FIG. 3 illustrates a device including an amplifier and a plurality of switches.

FIG. 4 illustrates a switch, and drain and gate signals of the switch, in accordance with an exemplary embodiment of the present disclosure.

FIG. 5 depicts a switch coupled to a resistor divider, in accordance with an exemplary embodiment of the present disclosure.

FIG. 6 illustrates a device including an amplifier and a plurality of switches, according to an exemplary embodiment of the present disclosure.

FIG. 7 depicts another device including an amplifier and a plurality of switches, in accordance with an exemplary embodiment of the present disclosure.

FIG. 8 illustrates yet another device including an amplifier and a plurality of switches, according to an exemplary embodiment of the present disclosure.

FIG. 9 depicts an amplifier and a resistor array, in accordance with an exemplary embodiment of the present disclosure.

FIG. 10 is a flowchart depicting a method, according to an exemplary embodiment of the present disclosure.

FIG. 11 shows an embodiment of an amplifier device, in accordance with an exemplary embodiment of the present disclosure.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

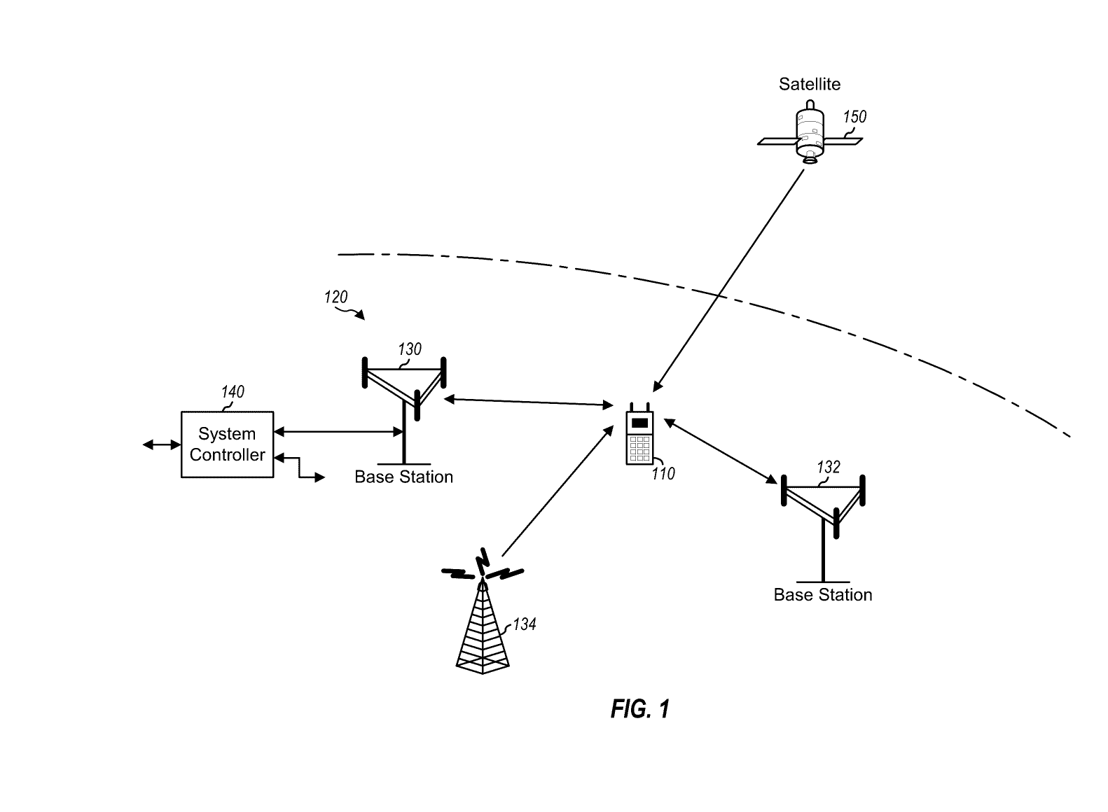

FIG. 1 shows a wireless device 110 communicating with a wireless communication system 120. Wireless system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless system 120 including two base stations 130 and 132 and one system controller 140. In general, a wireless system may include any number of base stations and any set of network entities.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may communicate with wireless system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1×, EVDO, TD-SCDMA, GSM, 802.11, etc.

Wireless device 110 may support carrier aggregation, which is operation on multiple carriers. Carrier aggregation may also be referred to as multi-carrier operation. Wireless device 110 may be able to operate in low-band (LB) covering frequencies lower than 1000 megahertz (MHz), mid-band (MB) covering frequencies from 1000 MHz to 2300 MHz, and/or high-band (HB) covering frequencies higher than 2300 MHz. For example, low-band may cover 698 to 960 MHz, mid-band may cover 1475 to 2170 MHz, and high-band may cover 2300 to 2690 MHz and 3400 to 3800 MHz. Low-band, mid-band, and high-band refer to three groups of bands (or band groups), with each band group including a number of frequency bands (or simply, “bands”). Each band may cover up to 200 MHz and may include one or more carriers. Each carrier may cover up to 20 MHz in LTE. LTE Release 11 supports 35 bands, which are referred to as LTE/UMTS bands and are listed in 3GPP TS 36.101. Wireless device 110 may be configured with up to five carriers in one or two bands in LTE Release 11.

In general, carrier aggregation (CA) may be categorized into two types—intra-band CA and inter-band CA. Intra-band CA refers to operation on multiple carriers within the same band. Inter-band CA refers to operation on multiple carriers in different bands.

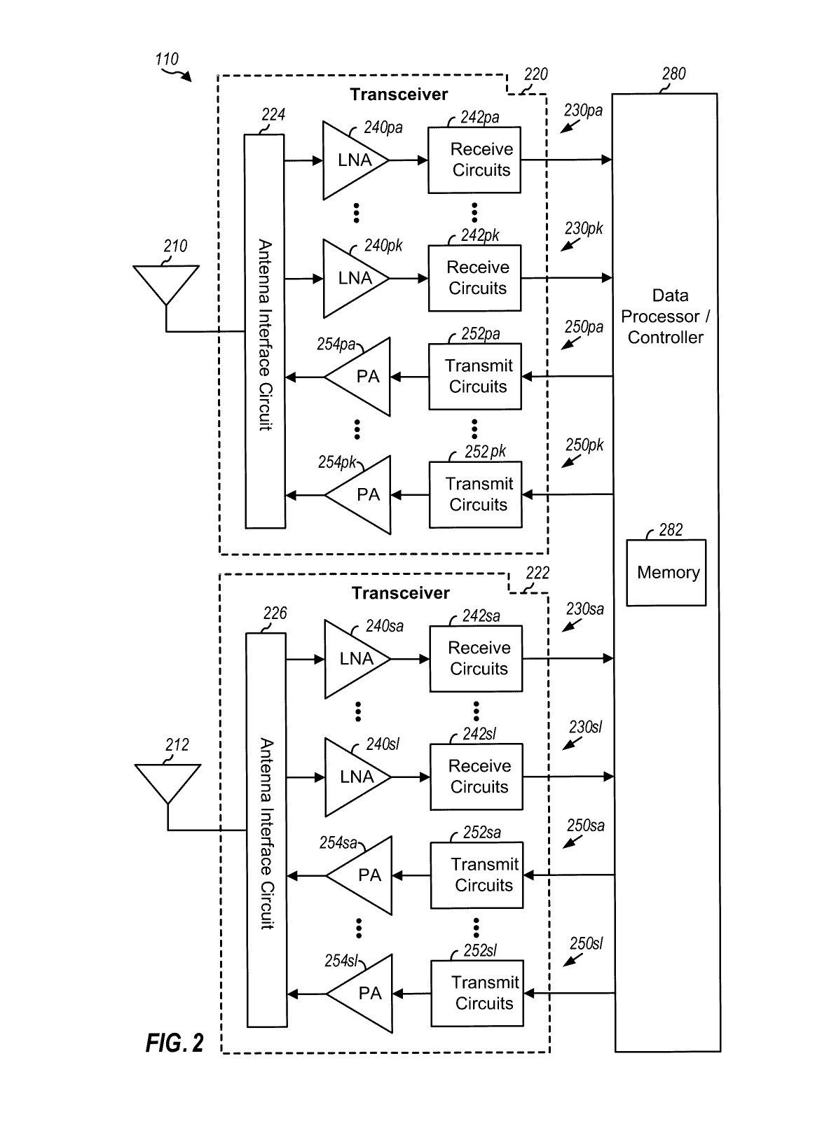

FIG. 2 shows a block diagram of an exemplary design of wireless device 110 in FIG. 1. In this exemplary design, wireless device 110 includes a transceiver 220 coupled to a primary antenna 210, a transceiver 222 coupled to a secondary antenna 212, and a data processor/controller 280. Transceiver 220 includes multiple (K) receivers 230pa to 230pk and multiple (K) transmitters 250pa to 250pk to support multiple frequency bands, multiple radio technologies, carrier aggregation, etc. Transceiver 222 includes L receivers 230sa to 230sl and L transmitters 250sa to 250sl to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230 includes an LNA 240 and receive circuits 242. For data reception, antenna 210 receives signals from base stations and/or other transmitter stations and provides a received RF signal, which is routed through an antenna interface circuit 224 and presented as an input RF signal to a selected receiver. Antenna interface circuit 224 may include switches, duplexers, transmit filters, receive filters, matching circuits, etc. The description below assumes that receiver 230pa is the selected receiver. Within receiver 230pa, an LNA 240pa amplifies the input RF signal and provides an output RF signal. Receive circuits 242pa downconvert the output RF signal from RF to baseband, amplify and filter the downconverted signal, and provide an analog input signal to data processor 280. Receive circuits 242pa may include mixers, filters, amplifiers, matching circuits, an oscillator, a local oscillator (LO) generator, a phase locked loop (PLL), etc. Each remaining receiver 230 in transceivers 220 and 222 may operate in a similar manner as receiver 230pa.

In the exemplary design shown in FIG. 2, each transmitter 250 includes transmit circuits 252 and a power amplifier (PA) 254. For data transmission, data processor 280 processes (e.g., encodes and modulates) data to be transmitted and provides an analog output signal to a selected transmitter. The description below assumes that transmitter 250pa is the selected transmitter. Within transmitter 250pa, transmit circuits 252pa amplify, filter, and upconvert the analog output signal from baseband to RF and provide a modulated RF signal. Transmit circuits 252pa may include amplifiers, filters, mixers, matching circuits, an oscillator, an LO generator, a PLL, etc. A PA 254pa receives and amplifies the modulated RF signal and provides a transmit RF signal having the proper output power level. The transmit RF signal is routed through antenna interface circuit 224 and transmitted via antenna 210. Each remaining transmitter 250 in transceivers 220 and 222 may operate in a similar manner as transmitter 250pa.

FIG. 2 shows an exemplary design of receiver 230 and transmitter 250. A receiver and a transmitter may also include other circuits not shown in FIG. 2, such as filters, matching circuits, etc. All or a portion of transceivers 220 and 222 may be implemented on one or more analog integrated circuits (ICs), RF ICs (RFICs), mixed-signal ICs, etc. For example, LNAs 240 and receive circuits 242 within transceivers 220 and 222 may be implemented on multiple IC chips, as described below. The circuits in transceivers 220 and 222 may also be implemented in other manners.

Data processor/controller 280 may perform various functions for wireless device 110. For example, data processor 280 may perform processing for data being received via receivers 230 and data being transmitted via transmitters 250. Controller 280 may control the operation of the various circuits within transceivers 220 and 222. A memory 282 may store program codes and data for data processor/controller 280. Data processor/controller 280 may be implemented on one or more application specific integrated circuits (ASICs) and/or other ICs.

Wireless device 110 may support CA and may (i) receive multiple downlink signals transmitted by one or more cells on multiple downlink carriers at different frequencies and/or (ii) transmit multiple uplink signals to one or more cells on multiple uplink carriers. Transmitters and receivers to support CA may be implemented on a single IC chip. However, it may be difficult or not possible to meet isolation requirements between the transmitters and receivers in certain transmit (TX) and receive (RX) bands due to limited pin-to-pin isolation on the IC chip.

For example, in the inter-CA mode, the isolation requirement between some TX and RX bands (e.g., UMTS Bands 4 and 17) may be 100 decibels (dB), which may be difficult or not possible to achieve since pin-to-pin isolation is worse than the isolation requirement. On-chip transmit filtering may improve pin-to-pin RX/TX isolation but (i) may degrade transmitter performance and (ii) may not reduce other RX/TX coupling mechanisms on the same IC chip. Furthermore, spurious signals from multiple PLLs and LO generators operating simultaneously on the same IC chip may degrade transmitter performance. Sensitivity of a receiver may also be degraded due to poor spurious and isolation performance.

In an aspect of the present disclosure, expandable transceivers and receivers implemented on multiple IC chips may be used to support CA and mitigate the problems described above. Transmitters and receivers on the multiple IC chips may be selected for use such that interference between these transmitters and receivers may be mitigated. As an example, for inter-band CA, a transmitter and a receiver on one IC chip may be used for communication on one band, and another transmitter and another receiver on another IC chip may be used for communication on another band. This may mitigate spurious and isolation problems encountered in the single-chip design.

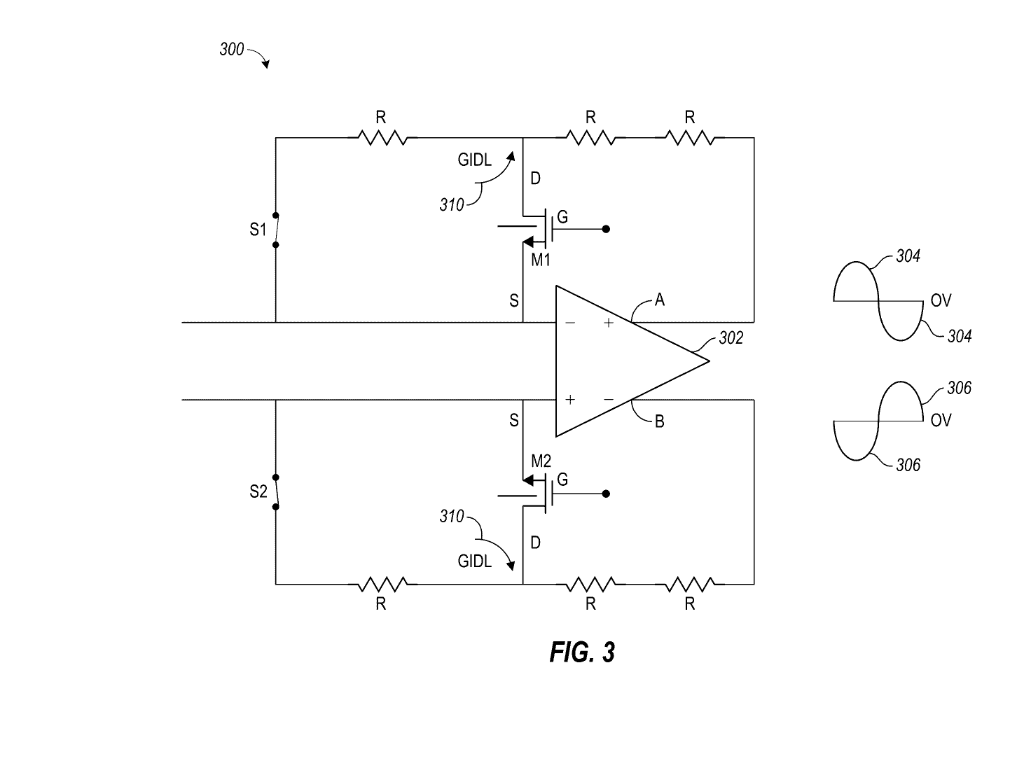

FIG. 3 depicts a device 300 including an amplifier 302, switches M1 and M2, switches 51 and S2, and a plurality of resistors R. Each of switch M1 and M2, which may comprise n-channel mosfet (NMOS) transistors, include a gate G, a drain D, and a source S. As illustrated, source S of switch M1 is coupled to a negative input of amplifier 302 and source S of switch M2 is coupled to a positive input of amplifier 302. Further, a signal 304 represents a positive output of amplifier 302 (i.e., at a node A) and a signal 306 represents a negative output of amplifier 302 (i.e., at a node B). Each of signal 304 and 306 have an average voltage of 0 volts.

As will be understood by a person having ordinary skill in the art, gate drain induced leakage (GDIL) is a phenomenon for excessive leakage current between a drain and substrate when the gate is biased with a negative voltage. When a gate is biased negatively, it results in an accumulation layer at the surface. This accumulation layer draws a large number of holes to the surface, which acts as a heavily doped p-region. The local depletion region at the surface becomes very narrow and the local electric field increases and consequently, the leakage current between drain and substrate increases. If there is a switch used in the feedback path of a high linearity amplifier, and if turning off this switch requires negative voltage, then a device may suffer from the inaccuracies of the extra leakage current as shown by arrows 310 in FIG. 3.

Exemplary embodiments, as described herein, are related to reducing gate induced drain leakage in electronic switches. According to one exemplary embodiment, a device may include an amplifier and at least one transistor coupled in a feedback path of the amplifier. Further, the device may include a circuit configured to modulate a gate of the at least one transistor with a signal comprising a scaled-down and shifted version of a signal at a drain of the at least one transistor.

Yet another exemplary embodiment may include a device comprising an amplifier and a negative reference voltage coupled to an output of the amplifier via a first resistor and a second resistor. The device may also include at least one first transistor coupled between the output of the amplifier and an input of the amplifier, wherein a gate of the at least one first transistor is configured to be switchably coupled between a plurality of resistors. A source of the at least one transistor may be coupled to the input of the amplifier, and a drain of the at least one first transistor may be coupled to the output of the amplifier via at least a third resistor.

According to another exemplary embodiment, the present disclosure includes methods for reducing gate induced drain leakage of a switch. Various embodiments of such a method may include receiving an input signal at an amplifier. The method may also include modulating a gate of a transistor coupled in a feedback path of the amplifier with a signal comprising a scaled-down and shifted version of a signal at the drain of the transistor.

Other aspects, as well as features and advantages of various aspects, of the present disclosure will become apparent to those of skill in the art though consideration of the ensuing description, the accompanying drawings and the appended claims.

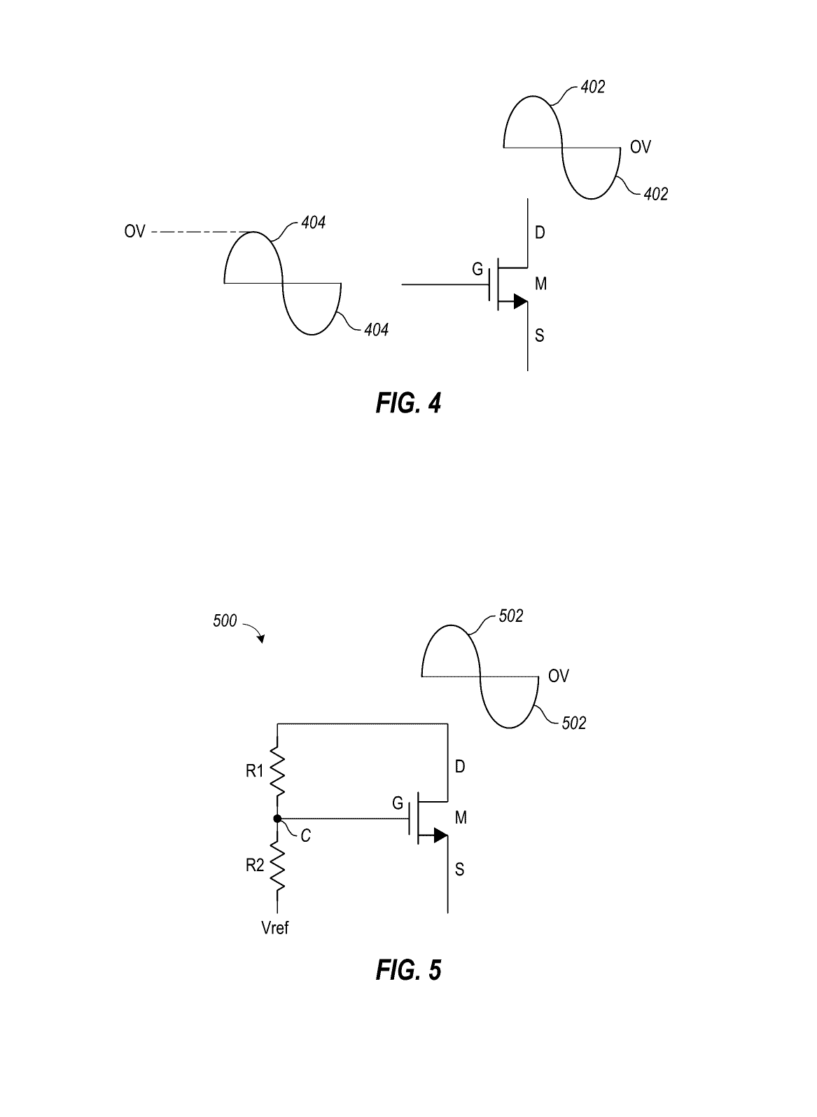

FIG. 4 illustrates a transistor M including a gate G, a drain D, and a source S. FIG. 4 further illustrates a signal 402, which represents a voltage at drain D of transistor M, and a signal 404, which represents a voltage at gate G of transistor M. It is noted that signal 404 is scaled-down (i.e., an amplitude of signal 404 is reduced) relative to signal 402, and signal 404 is shifted (i.e., an average voltage of signal 404 is less) relative to signal 402. As will be appreciated by a person having ordinary skill in the art, leakage current may be a function of the gate bias as well as the drain-bulk junction voltage. According to one exemplary embodiment of the present disclosure, when transistor M is “off” (i.e., in a non-conductive state), gate G of transistor M may be modulated with a scaled-down (i.e., reduced amplitude) and shifted (i.e., reduced average voltage) version of the drain signal. The gate signal may cause transistor M to turn off, and in addition, for relatively large drain voltage, gate G will be biased “less negatively” to reduce GIDL, and for a relatively small drain voltage, gate G will be biased “more negatively” since leakage may be less pronounced.

FIG. 5 illustrates a device 500, according to an exemplary embodiment of the present disclosure. Device 500 includes transistor M including gate G, drain D, and source S. Further, device 500 includes a resistor divider including resistors R1 and R2. As illustrated, one end of resistor R1 is coupled to drain D of transistor M and another end of resistor R1 is coupled to a node C, which is further coupled to gate G of transistor M. Moreover, one end of resistor R2 is coupled to node C and another end is coupled to a reference voltage Vref, which may comprise a negative reference voltage. In addition, source S of transistor M is configured for coupling to another component (e.g., amplifier, load, etc.) In the embodiment illustrated in FIG. 5, transistor M is configured to be biased (i.e., in a non-conductive “off” state) by the resistor divider (i.e., resistors R1 and R2) coupled to drain D. FIG. 5 further illustrates a signal 502, which represents a voltage at drain D of transistor M.

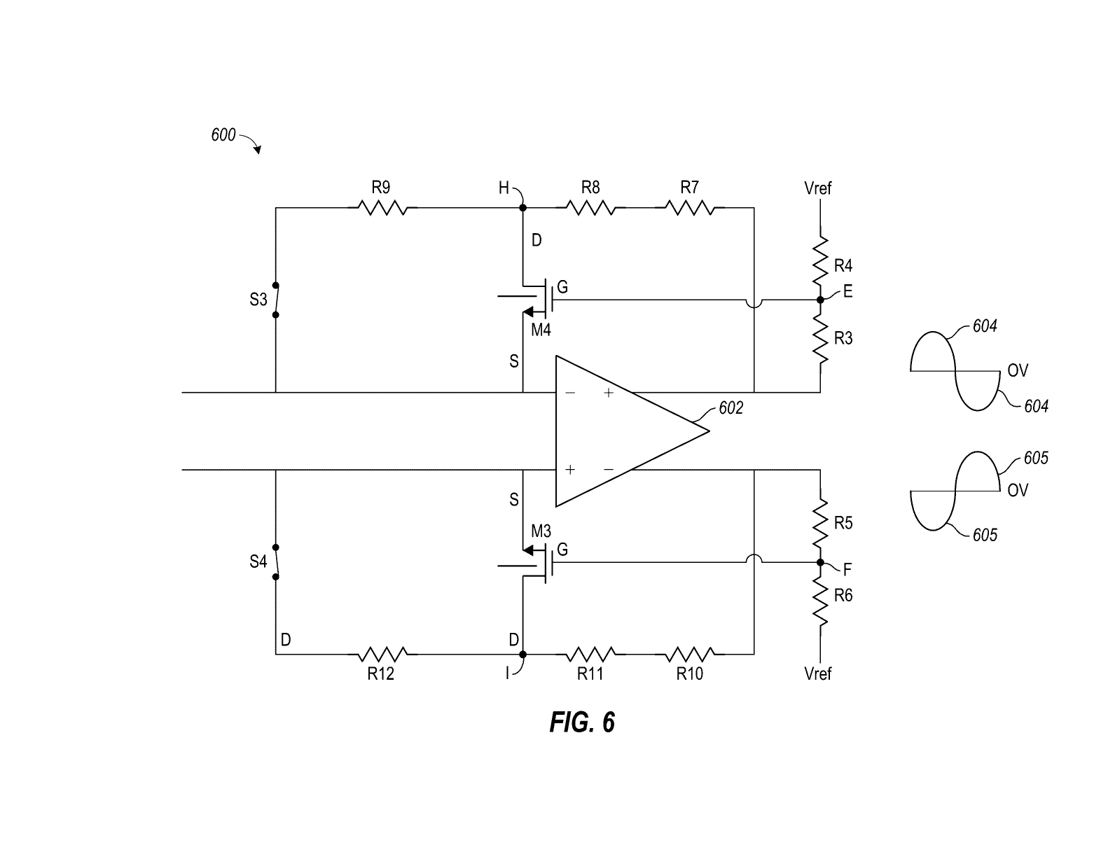

FIG. 6 illustrates a device 600, in accordance with another exemplary embodiment of the present disclosure. Device 600 includes transistors M3 and M4, each of which includes a gate G, a drain D, and a source S. Device 600 also includes an amplifier 602 having a positive input coupled to source S of transistor M4 and one end of a switch S3. Amplifier 602 also includes a negative input coupled to a source S of transistor M3 and one end of a switch S4.

Further, device 600 includes a resistor divider including resistors R3 and R4. As illustrated, one end of resistor R3 is coupled to a positive output of amplifier 602 and another end of resistor R3 is coupled to a node E, which is further coupled to gate G of transistor M4. Moreover, one end of resistor R4 is coupled to node E and another end of resistor R4 is coupled to reference voltage Vref, which may comprise a negative reference voltage. Additionally, device 600 includes resistors R8 and R7 coupled in series between a node H and the positive output of amplifier 602. A resistor R9 is coupled between node H and a second end of switch S3. Node H is further coupled to drain D of transistor M4.

Device 600 further includes a resistor divider including resistors R5 and R6. As illustrated, one end of resistor R5 is coupled to a negative output of amplifier 602 and another end of resistor R5 is coupled to a node F, which is further coupled to gate G of transistor M3. Moreover, one end of resistor R6 is coupled to node F and another end of resistor R6 is coupled to reference voltage Vref, which may comprise a negative reference voltage. Moreover, device 600 includes resistors R11 and R10 coupled in series between a node I and the negative output of amplifier 602. A resistor R12 is coupled between node I and a second end of switch S4. Node I is further coupled to drain D of transistor M3. FIG. 6 further illustrates a signal 604, which represents a signal at the positive output of amplifier 602, and a signal 605, which represents a signal at the negative output of amplifier 602.

In the embodiment of FIG. 6, to avoid loading a drain of a transistor (e.g., transistor M3 and/or transistor M4) with resistors, any node voltage that has the same waveform signature (i.e., of the signal at the drain of the transistor), and can allow resistor loading, may be used to modulate the gate of the transistor. More specifically, as an example, a copy of an output voltage (i.e., output of amplifier 602) may be used instead of a drain voltage to avoid loading the drain of the transistor. It is noted that loading the output voltage may be permissible since it is a low-impedance node. As will be understood, a signal applied to the gate of the transistor may comprise a scaled-down and shifted version of a drain signal (i.e., a signal at the drain of the transistor).

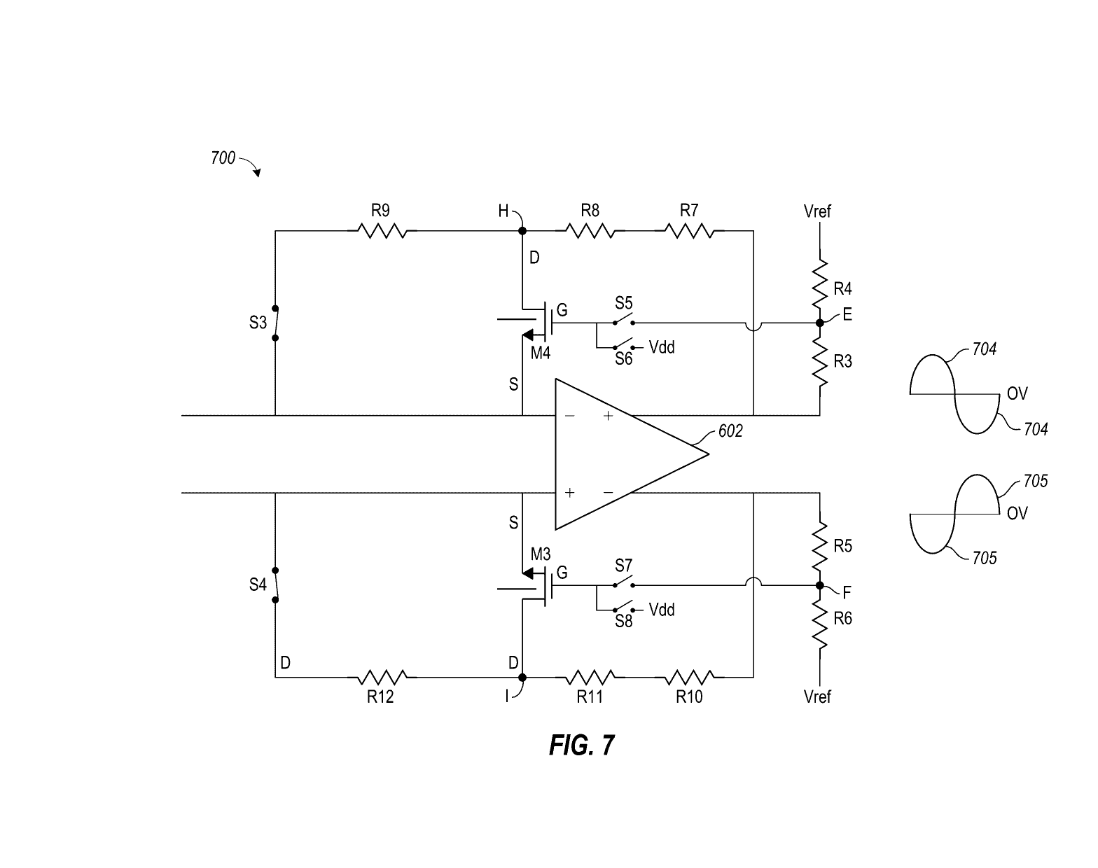

FIG. 7 depicts another exemplary device 700, according to an exemplary embodiment of the present disclosure. In addition to the elements of device 600, device 700 further includes switches S5-S8. As will be appreciated, switch S5 is configured to couple gate G of transistor M4 to node E, causing transistor M4 to operate in a non-conductive “off” state. Switch S6 is configured to couple gate G of transistor M4 to a supply voltage Vdd, causing transistor M4 to operate in a conductive “on” state. Further, switch S7 is configured to couple gate G of transistor M3 to node F, causing transistor M3 to operate in a non-conductive “off” state. Switch S8 is configured to couple gate G of transistor M3 to supply voltage Vdd, causing transistor M3 to operate in a conductive “on” state. FIG. 7 further illustrates a signal 704, which represents a signal at the positive output of amplifier 602, and a signal 705, which represents a signal at the negative output of amplifier 602. It is noted that resistors may be used for the feedback switches (e.g., transistors M3 and M4) since the scaling factor is not very critical to eliminate the GIDL extra leakage.

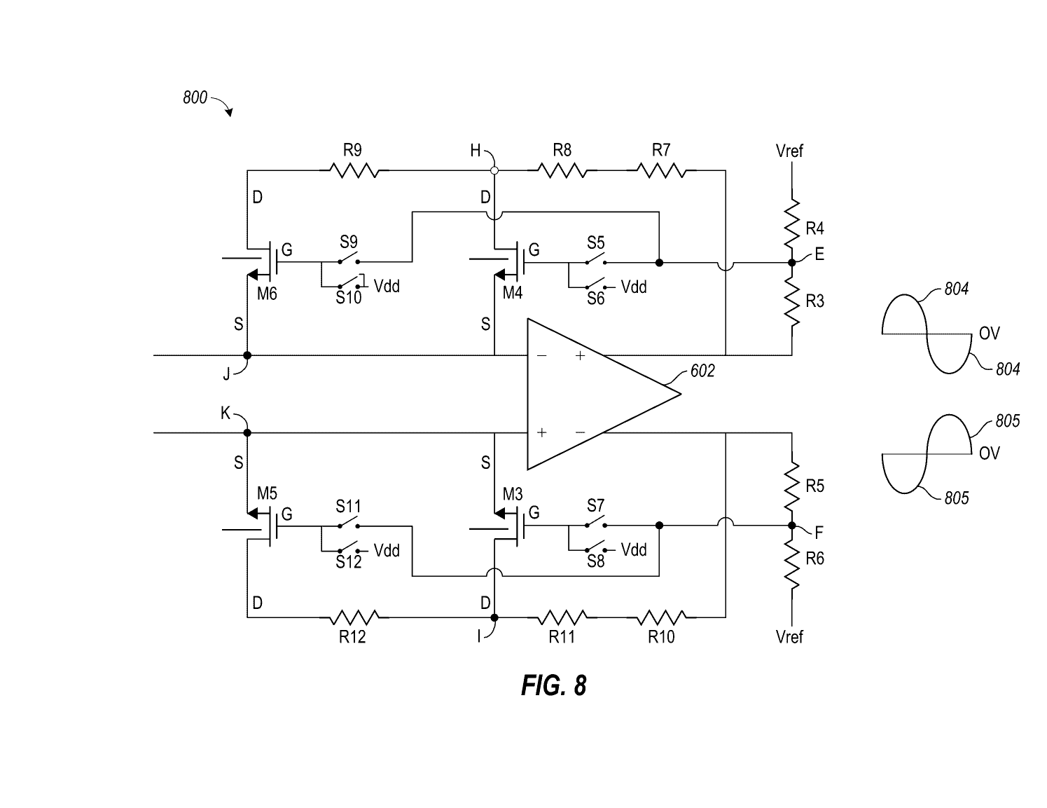

With reference to FIG. 8, another exemplary device 800 is illustrated. In addition to the elements of device 700, device 800 further includes transistors M5 and M6, which may respectively represent switches S4 and S3 of device 700, and switches S9-S12. A drain D of transistor M6 is coupled to resistor R9 and a source of transistor M6 is coupled to a node J, which is coupled to the negative input of amplifier 602. Switch S9 is configured to couple a gate G of transistor M6 to node E, causing transistor M6 to operate in a non-conductive “off” state. Switch S10 is configured to couple gate G of transistor M6 to a supply voltage Vdd, causing transistor M6 to operate in a conductive “on” state.

A drain D of transistor M5 is coupled to resistor R12 and a source of transistor M5 is coupled to a node K, which is coupled to the positive input of amplifier 602. Switch S11 is configured to couple a gate G of transistor M5 to node F, causing transistor M5 to operate in a non-conductive “off” state. Switch S12 is configured to couple gate G of transistor M5 to a supply voltage Vdd, causing transistor M5 to operate in a conductive “on” state. FIG. 8 further illustrates a signal 804, which represents a signal at the positive output of amplifier 602, and a signal 805, which represents a signal at the negative output of amplifier 602.

The devices and methods disclosed herein may be configured to reduce, and possibly eliminate, GIDL leakage associated with any suitable electronic switch. In one non-limiting example, the disclosed embodiments may reduce, and possibly eliminate, GIDL leakage associated with a full differential amplifier, wherein common mode at the output is set to zero. Further, switches in the feedback may be used for gain control. In one example, embodiments of the present disclosure improved the overall amplifier distortion from 115 dB to 125 dB, providing a very high linearity solution.

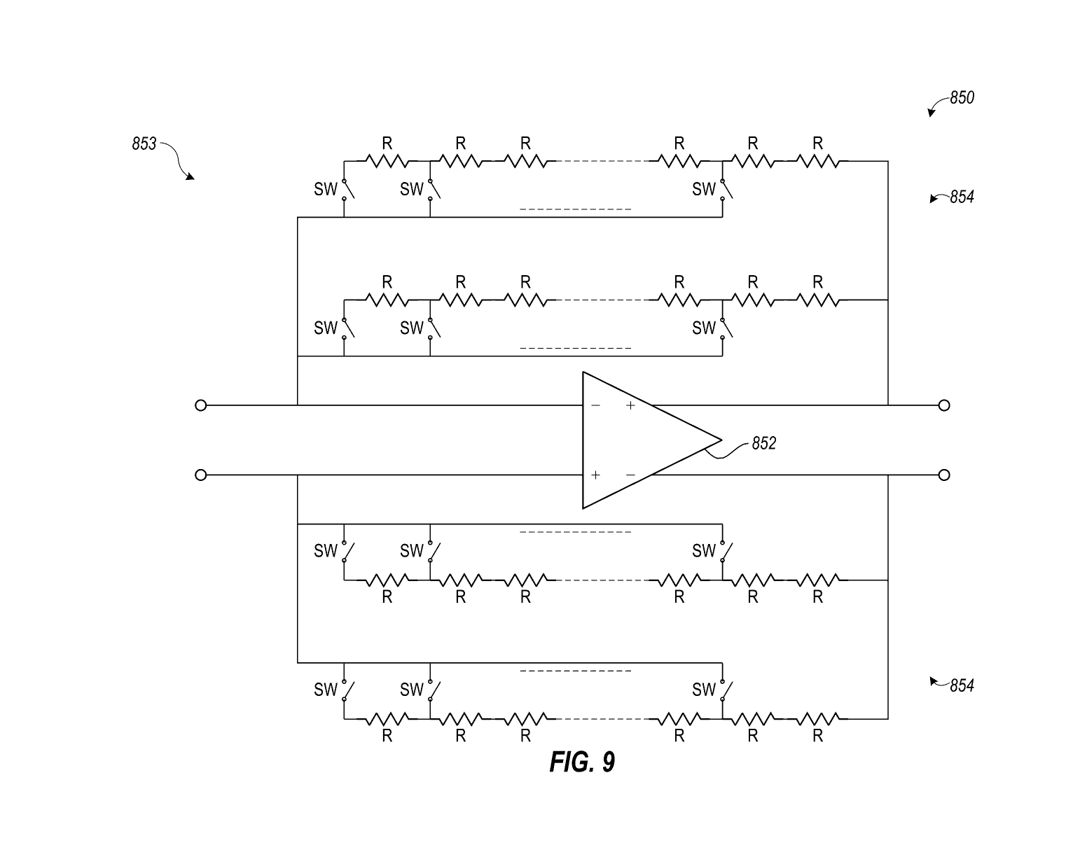

FIG. 9 depicts a device 850 including an amplifier 852 and a feedback network 853, according to an exemplary embodiment of the present disclosure. Feedback network 853 includes a resistor array 854, which includes a plurality of switches (e.g., transistors M) and resistors R. Resistor array 854 includes a first plurality of selectable paths coupled between a positive output and a negative input of amplifier 852. Further, resistor array 854 includes a second plurality of selectable paths coupled between a negative output and a positive input of amplifier 852. Each path within feedback network 853 is independently selectable for providing variable gain via at least one switch of the plurality of switches (e.g., transistors M). It is noted that each switch (e.g., transistor M) within network 853 may comprise a transistor configured according to one or more embodiments disclosed above.

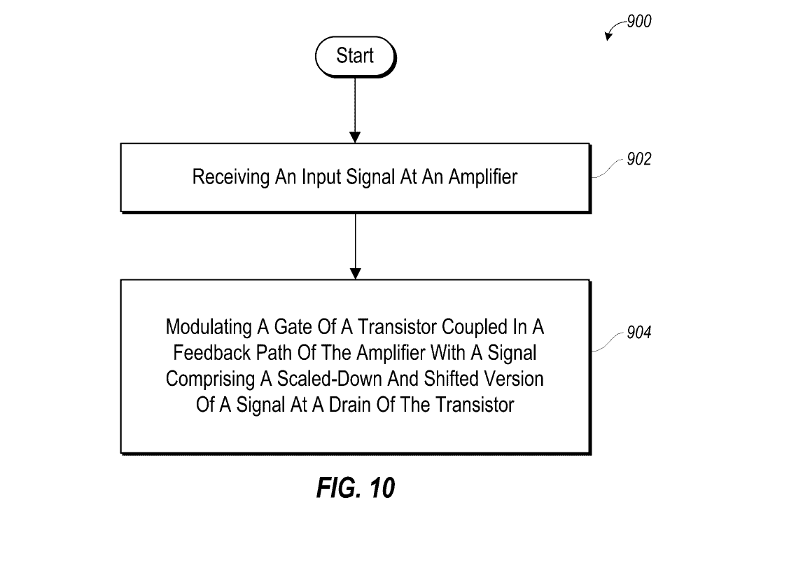

FIG. 10 is a flowchart illustrating a method 900, in accordance with one or more exemplary embodiments. Method 900 may include receive an input signal at an amplifier (depicted by numeral 902). Method 900 may also include modulate a gate of a transistor coupled in a feedback path of the amplifier with a signal comprising a scaled-down and shifted version of a signal at a drain of the transistor (depicted by numeral 904).

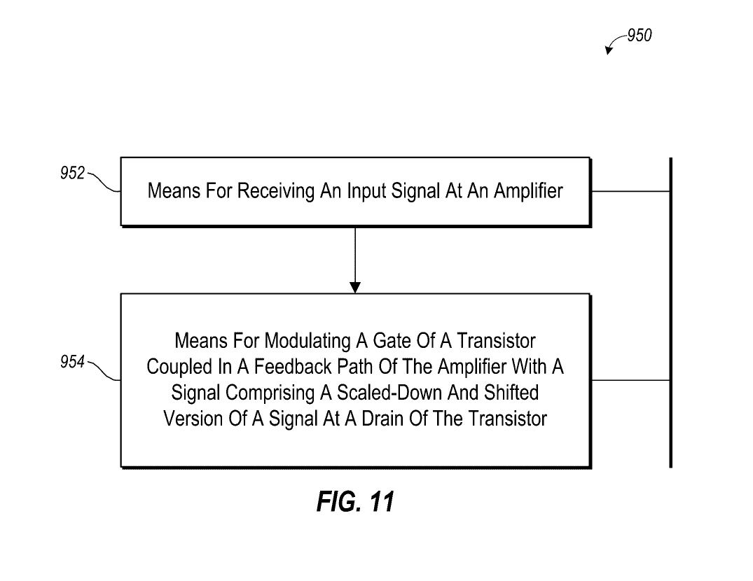

FIG. 11 shows an exemplary embodiment of an amplifier device 950. For example, device 950 is suitable for use as device 600, device 700, device 800 and/or device 850 as shown in FIGS. 6-9. According to one embodiment, device 950 is implemented by one or more modules configured to provide the functions as described herein. For example, in an aspect, each module comprises hardware and/or hardware executing software.

Device 950 comprises a first module comprising means (952) for receiving an input signal at an amplifier. For example, amplifier 602 (see FIGS. 5-8) may include at least one input terminal for receiving an input signal.

Device 950 also comprises a second module comprising means (954) for modulating a gate of a transistor coupled in a feedback path of the amplifier with a signal comprising a scaled-down and shifted version of a signal at a drain of the transistor. For example, a signal at node E (see FIGS. 6-8) may be used to modulate a gate of transistor M4 and a signal at node F (see FIGS. 6-8) may be used to modulate a gate of transistor M3 (see FIGS. 6-8).

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

It is noted that combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. A device, comprising:
an amplifier;
at least one transistor coupled in a feedback path of the amplifier; and
a circuit configured to modulate a gate of the at least one transistor with a signal comprising a scaled-down and shifted version of a signal at a drain of the at least one transistor.

2. The device of claim 1, an output of the amplifier coupled to a negative reference voltage via a first resistor and a second resistor and to the drain of the at least one transistor via at least a third resistor, a source of the at least one transistor coupled to an input of the amplifier and the gate of the at least one transistor configured to couple between the first resistor and the second resistor to operate the at least one transistor in a non-conductive state.

3. The device of claim 2, further comprising at least one other transistor comprising a gate, a drain, and a source, the amplifier having a second input and a second output, the second output coupled to the negative reference voltage via a fourth resistor and a fifth resistor and to the drain of the at least one other transistor via at least a sixth resistor, the source of the at least one other transistor coupled to the second input of the amplifier and the gate of the at least one other transistor configured to couple between the fourth resistor and the fifth resistor to operate the at least one other transistor in a non-conductive state.

4. The device of claim 3, the drain of the at least one transistor further coupled to the input of the amplifier via a seventh resistor and the drain of the at least one other transistor further coupled to the second input of the amplifier via an eighth resistor.

5. The device of claim 3, wherein the at least one other transistor is further configured to operate in a conductive state based on a supply voltage received at the gate of the least one other transistor.

6. The device of claim 2, wherein the at least one transistor is further configured to operate in a conductive state based on a supply voltage received at the gate of the at least one transistor.

7. The device of claim 2, wherein during a non-conductive state, the gate of the at least one transistor is modulated with a signal comprising the scaled-down and shifted version of the signal at the drain of the at least one transistor.

8. The device of claim 2, further comprising a switch configured to switchably couple the gate of the at least one transistor between the first resistor and the second resistor.

9. The device of claim 1, further comprising a feedback network comprising a plurality of feedback paths, at least one feedback path selectable for varying a gain via one or more transistors of the at least one transistor.

10. The device of claim 9, wherein the plurality of paths includes a first plurality of selectable paths coupled between a positive output of the amplifier and a negative input of the amplifier and a second plurality of selectable paths coupled between a negative output of the amplifier and a positive input of the amplifier.

11. The device of claim 1, further comprising a negative reference voltage coupled to an output of the amplifier via a first resistor and a second resistor.

12. The device of claim 11, wherein the gate of the at least one transistor is switchably coupled between the first and second resistors.

13. The device of claim 1, wherein during a non-conductive state, the gate of the at least one transistor is configured to be modulated with the signal having a waveform substantially the same as a waveform of the signal at the drain of the at least one transistor and a reduced amplitude and a reduced average voltage relative to the signal at the drain of the at least one transistor.

14. The device of claim 1, further comprising a wireless communication device comprising the amplifier and the at least one transistor.

15. The device of claim 1, wherein the at least one transistor is configured to control a gain of the amplifier.

16. The device of claim 1, the at least one transistor comprising a plurality of transistors, wherein each transistor of the plurality of transistors comprises a gate configured to switchably receive one of a negative reference voltage via a resistor and a supply voltage.

17. A method, comprising:
receiving an input signal at an amplifier; and
modulating a gate of a transistor coupled in a feedback path of the amplifier with a signal comprising a scaled-down and shifted version of a signal at a drain of the transistor.

18. The method of claim 17, wherein modulating a gate comprises modulating the gate of the transistor with the signal having a waveform substantially the same as a waveform of the signal at the drain and a reduced amplitude and a reduced average voltage relative to the signal at the drain of the transistor.

19. A device, comprising:
means for receiving an input signal at an amplifier; and
means for modulating a gate of a transistor coupled in a feedback path of the amplifier with a signal comprising a scaled-down and shifted version of a signal at a drain of the transistor.

20. The device of claim 19, wherein the means for modulating comprises means for modulating the gate of the transistor with the signal having a reduced amplitude and a reduced average voltage relative to the signal at the drain of the transistor.
